(19) United States
(12) Patent Application Publication
(10) Pub. No.: US 2026/0371700 A1
(43) Pub. Date: Nov. 19, 2026

(54) AMORPHIZATION OF SILICON SUBSTRATE BEFORE REMOVAL IN STACKED TRANSISTORS

(71) Applicant: Taiwan Semiconductor Manufacturing Co., Ltd., Hsinchu (TW)

(72) Inventors: Shao-Tse Huang, Hsinchu (TW); Wei-De Ho, Hsinchu (TW); Shih-Chi Lin, Hsinchu (TW)

(21) Appl. No.: 19/751,759

(22) Filed: Jul. 23, 2026

Related U.S. Application Data
(63) Continuation of application No. 19/095,884, filed on Mar. 31, 2025.
(60) Provisional application No. 63/723,665, filed on Nov. 22, 2024.

(51) Int. Cl. H10D 84/01; H10D 62/10; H10D 64/23; H10D 84/85; H10P 30/20

(52) U.S. Cl. CPC H10D 84/0186; H10D 62/116; H10D 64/258; H10D 84/0172; H10D 84/0184; H10D 84/0188; H10D 84/851; H10D 84/856; H10P 30/20

(57) ABSTRACT

A semiconductor device and the method of forming the same are provided. The semiconductor device may include a first source/drain region, a first nanostructure on a sidewall of the first source/drain region, a first gate structure around the first nanostructure, a first isolation region and a second isolation region on the first gate structure, and a dielectric layer over the first source/drain region and the first gate structure. The first isolation region and the second isolation region may each comprise a first dielectric material and a first dopant. The dielectric layer may extend between the first isolation region and the second isolation region. The dielectric layer may comprise a second dielectric material. The dielectric layer may be free of the first dopant.

### PRIORITY CLAIM AND CROSS-REFERENCE

This application is a continuation of U.S. Patent Application No. 19/095,884, filed Mar. 31, 2025, which application claims the benefit of U.S. Provisional Application No. 63/723,665, filed on Nov. 22, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2, 3, 4, 5, 6, 7A, 7B, 8A, 8B, 9A, 9B, 10A, 10B, 11A, 11B, 12A, and 12B, are various views of intermediate stages in the manufacturing of a stacking transistor in accordance with some embodiments.

FIGS. 13A and 13B are cross-sectional views of a stacking transistor in accordance with some embodiments.

FIGS. 14A and 14B are cross-sectional views of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor comprising an upper transistor and a lower transistor that are vertically stacked. Each of the upper and lower transistors may include gate structures wrapping around respective semiconductor nanostructures and source/drain regions on sidewalls of the respective semiconductor nanostructures. The semiconductor nanostructures may be formed over respective semiconductor fins, which may be partially or completely removed during an etching process after the gate structures and the source/drain regions are formed. Due to amorphization of the semiconductor fins by doping the semiconductor fins with a dopant, the semiconductor fins may be partially or completely removed without damaging the gate structures or the source/drain regions during the etching process. As a result, the performance and reliability of the stacking transistor may be improved.

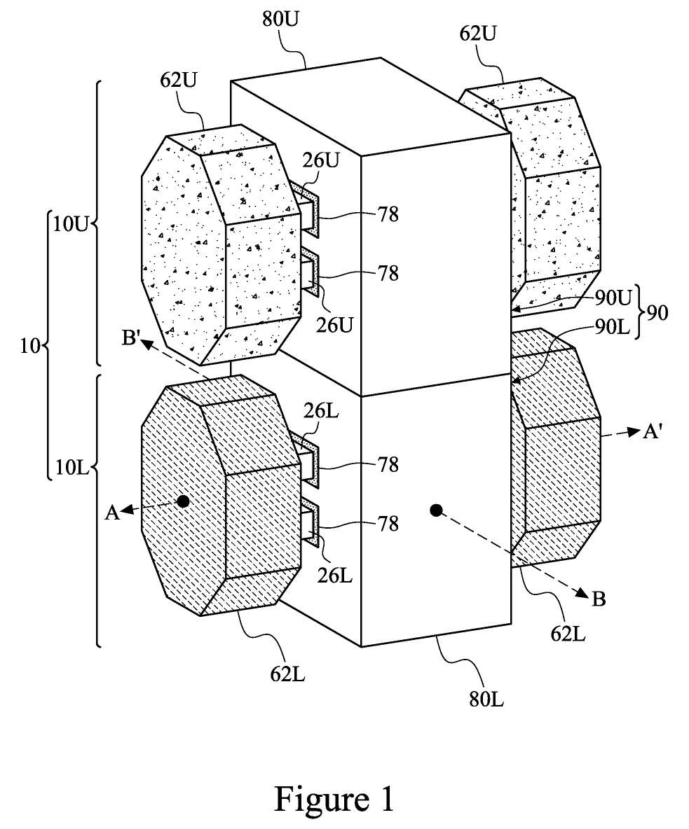

FIG. 1 illustrates an example of a stacking transistor 10 in accordance with some embodiments. FIG. 1 is a perspective view, and some features of the stacking transistor are omitted for illustration clarity. The stacking transistor includes multiple vertically stacked FETs. For example, a stacking transistor may include a lower nanostructure-FET 10L of a first device type (e.g., n-type or p-type) and an upper nanostructure-FET 10U of a second device type (e.g., p-type or n-type). When the stacking transistor is a Complementary Field-Effect Transistors (CFET), the second device type of the upper nanostructure-FET 10U is opposite to the first device type of the lower nanostructure-FET 10L. The upper nanostructure-FETs 10U and lower nanostructure-FET 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors, Nano Field-effect Transistors (nano-FETs), Fin Field Effect Transistors (finFETs), or the like.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-section A-A' and B-B’. Reference cross-section A-A' may be a vertical cross-section that is parallel to a longitudinal axis of the semiconductor nanostructures 26 of the stacking transistor 10 and in a direction of, for example, a current flow between the source/drain regions 62 of the stacking transistor 10. Reference cross-section B-B' may be a vertical cross-section that is perpendicular to the reference cross-section A-A’ and extend through the gate electrodes 80. The reference cross-sections A-A' and B-B’ in FIG. 1 may correspond to the reference cross-sections A-A' and B-B’ shown in some of the subsequent top-down view figures.

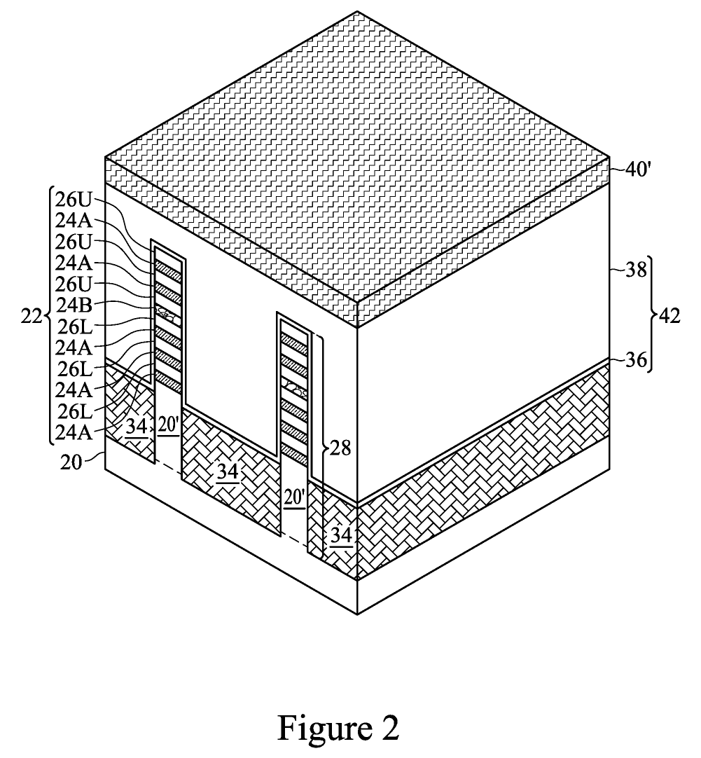

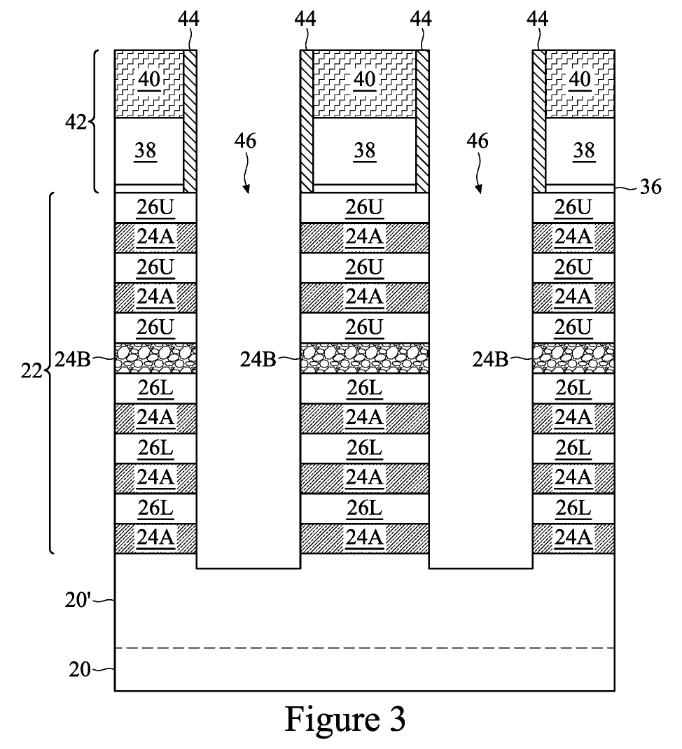

FIGS. 2-12B are various views of intermediate stages in the manufacturing of a stacking transistor including lower nanostructure-FETs and upper nanostructure-FETs, which may be similar to the stacking transistor 10 shown in FIG. 1, in accordance with some embodiments. FIG. 2 is a perspective view and FIGS. 3-12B are cross-sectional views of a portion of the structure shown in FIG. 2. In FIG. 2, a wafer, which includes substrate 20, is provided. The substrate 20 may be a semiconductor substrate formed of a crystalline semiconductor material. The substrate 20 may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor, the like, or combinations thereof.

Semiconductor strips 28 are formed extending upwards from the substrate 20. Each of semiconductor strips 28 includes semiconductor fin 20’ (patterned portions of the substrate 20) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent processes without significantly removing the semiconductor nanostructures 26. In some embodiments, the semiconductor nanostructures 26 are formed of silicon, the dummy nanostructures 24A are formed of silicon germanium, and the dummy nanostructures 24B are formed of germanium or silicon germanium with a higher germanium atomic percentage than the dummy nanostructures 24A.

The lower semiconductor nanostructures 26L may act as channel regions for lower nanostructure-FETs of the stacking transistor. The upper semiconductor nanostructures 26U may act as channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B may be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20’, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

STI regions 34 are formed over the substrate 20 and between adjacent semiconductor strips 28. The STI regions 34 may be on sidewalls of the semiconductor fins 20’. The STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric liner and the dielectric material are recessed to define the STI regions 34, such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layer 36 on the semiconductor strips 28 and forming a dummy gate layer 38 over the dummy dielectric layer 36. Dummy dielectric layer 36 may be formed of, for example, silicon oxide, silicon nitride, a combination thereof, or the like, and may be deposited or thermally grown according to acceptable techniques. The dummy gate layer 38 may be deposited, for example, through Physical Vapor Deposition (PVD), CVD, or other techniques, and then planarized, such as by a CMP process. The material of dummy gate layer 38 may be selected from a group including amorphous silicon, polycrystalline-silicon (polysilicon), poly-crystalline silicon-germanium (poly-SiGe), or the like.

A mask layer 40’ is formed over the planarized dummy gate layer 38. The mask layer 40’ may comprise, silicon nitride, silicon oxynitride, or the like. Then the mask layer 40’ may be patterned by suitable photolithography and etching processes to form a mask 40 (shown FIG. 3), which may be then used to pattern dummy gate layer 38 and the dummy dielectric layer 36. The mask 40, the remaining portions of the dummy gate layer 38, and the dummy dielectric layer 36 may be referred to as the dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. The mask 40, and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20’. The bottom surfaces of the source/drain recesses 46 may be at a level above, below, or level with the top surfaces of the STI regions 34 (not shown). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

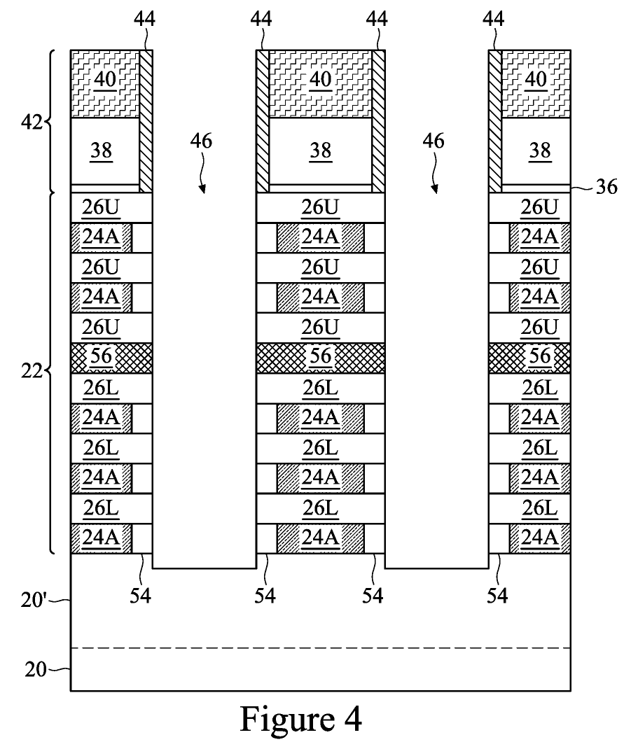

In FIG. 4, the dummy nanostructures 24A are partially removed and the dummy nanostructure 24B are completely removed. Then inner spacers 54 and dielectric isolation layers 56 are formed. After the dummy nanostructures 24A are partially removed, sidewalls of the dummy nanostructures 24A may be recessed. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U, the lower semiconductor nanostructures 26L, or the semiconductor fins 20’. The etching process may remove the dummy nanostructures 24A at a slower rate than the dummy nanostructure 24B.

In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 warp around the sidewalls of the semiconductor nanostructures 26 (see FIG. 2), the dummy gate stacks 42 may support the upper semiconductor nanostructures 26U so that the upper semiconductor nanostructures 26U do not collapse upon the complete removal of the dummy nanostructures 24B.

The inner spacers 54 may be formed on the recessed sidewalls of the dummy nanostructures 24A. The dielectric isolation layers 56 may be formed in spaces the dummy nanostructures 24B occupied before being removed. Source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U from the lower semiconductor nanostructures 26L.

The inner spacers 54 and the dielectric isolation layers 56 may be formed by conformally depositing a suitable dielectric material in the source/drain recesses 46, on the sidewalls the dummy nanostructures 24A, and between the bottom upper semiconductor nanostructures 26U and the top lower semiconductor nanostructures 26L. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

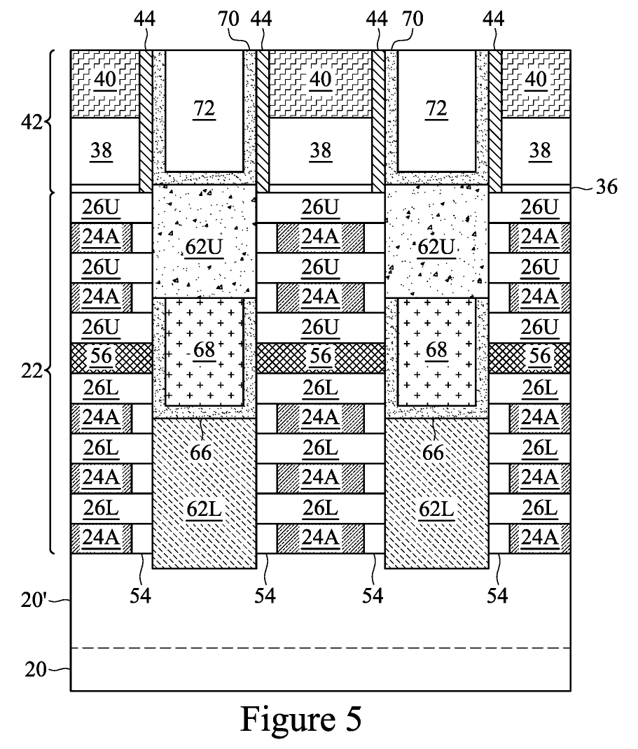

In FIG. 5, lower source/drain regions 62L, upper epitaxial source/drain regions 62U, first contact etch stop layers (CESLs) 66, first inter-layer dielectrics (ILDs) 68, second CESLs 70, and second ILDs 72 are formed in the source/drain recesses 46. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The upper epitaxial source/drain regions 62U are in contact with the upper semiconductor nanostructures 26U and are not in contact with the lower semiconductor nanostructures 26L. The lower epitaxial source/drain regions 62L are in contact with the inner spacers 54, which electrically insulate the lower epitaxial source/drain regions 62L from the dummy nanostructures 24A. The upper epitaxial source/drain regions 62U are in contact with inner spacers 54, which electrically insulate the upper epitaxial source/drain regions 62U from the dummy nanostructures 24A. The dummy nanostructures 24A will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L to merge.

The first CESLs 66 and the first ILDs 68 are formed over the lower epitaxial source/drain regions 62L. The first CESLs 66 may be formed of a dielectric material having a high etching selectivity from the etching of the first ILDs 68, such as silicon nitride, silicon oxide, silicon oxynitride, or the like, which may be formed by any suitable deposition process, such as CVD, ALD, or the like. The first ILDs 68 may be formed of a dielectric material, which may be deposited by any suitable method, such as CVD, plasma-enhanced CVD (PECVD), or FCVD. The applicable dielectric material of the first ILDs 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILDs 68, followed by a planarization process and then an etch-back process. In some embodiments, the first ILDs 68 are etched first, leaving the conformal CESL layer unetched. An anisotropic etching process is then performed to remove the portions of the conformal CESL layer higher than the recessed first ILDs 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant.

As a result of the epitaxy processes used for forming the upper epitaxial source/drain regions 62U, upper surfaces of the upper epitaxial source/drain regions 62U have facets which expand laterally outward beyond sidewalls of the multi-layer stacks 22. In some embodiments, adjacent upper epitaxial source/drain regions 62U remain separated after the epitaxy process is completed. In other embodiments, these facets cause neighboring upper epitaxial source/drain regions 62U to merge.

After the upper epitaxial source/drain regions 62U are formed, second CESLs 70 and second ILDs 72 are formed. The materials and the formation methods may be similar to the materials and the formation methods of the first CESLs 66 and the first ILDs 68, respectively. The formation process may include depositing the conformal CESL layer and the second ILDs 72, and performing a planarization process to remove the excess portion of the corresponding layers. After the planarization process, top surfaces of the second ILDs 72, the gate spacers 44, and mask 40 are substantially coplanar (within process variations). In the illustrated embodiment, the mask 40 remain after the removal process. In other embodiments, the mask 40 are removed such that the top surfaces of the dummy gate layers 38 are exposed.

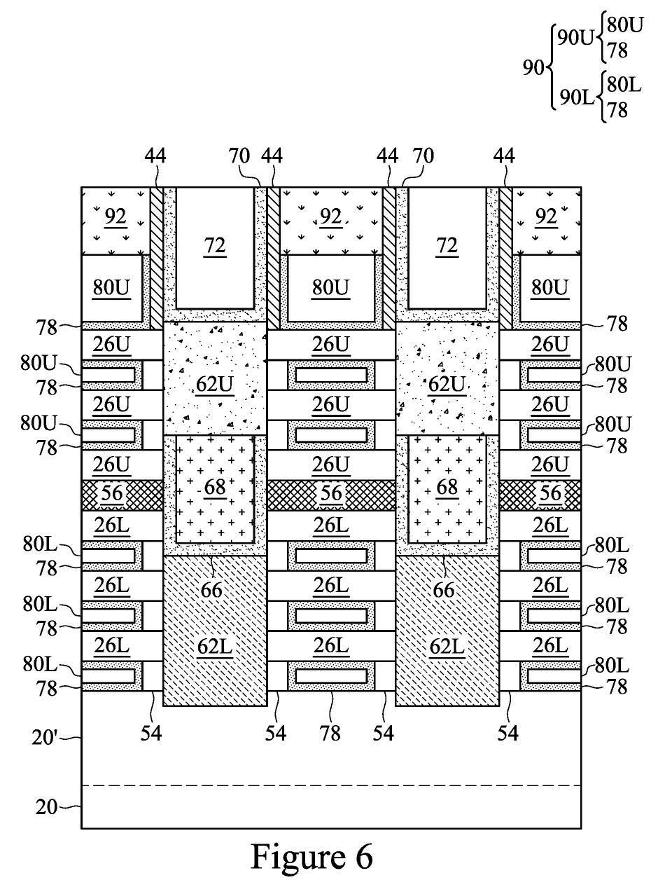

In FIG. 6, a gate replacement process to replace the dummy gate stacks 42 and the dummy nanostructures 24A with gate structures 90 is performed. The gate replacement process may include first removing the dummy gate stacks 42 and the dummy nanostructures 24A. The dummy gate stacks 42 may be removed by one or more suitable etching processes. The dummy nanostructures 24A may be then removed by an additional suitable etching process. The etching process that removes the dummy nanostructures 24A may selectively remove the material of the dummy nanostructures 24A without significantly removing the material(s) of the semiconductor nanostructures 26. In the embodiments where the dummy nanostructures 24A comprise silicon germanium, and the semiconductor nanostructures 26 comprise silicon, the etching process may be a wet isotropic etching process and etchants such as tetramethylammonium hydroxide, ammonium hydroxide, or the like may be used.

Then, gate dielectrics 78 may be deposited in the recesses between the gate spacers 44 and on the exposed semiconductor nanostructures 26. The gate dielectrics 78 may be conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20'; on the top surfaces, the sidewalls, and the bottom surfaces of the semiconductor nanostructures 26; and on the sidewalls of the inner spacers 54.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 may be illustrated, the gate dielectrics 78 may include multiple layers, such as an interfacial layer and an overlying high-k dielectric layer.

Lower gate electrodes 80L may be formed on the gate dielectrics 78 around the lower semiconductor nanostructures 26L. The lower gate electrodes 80L may wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

The lower gate electrodes 80L may be formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

In some embodiments, isolation layers (not illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Upper gate electrodes 80U may be formed on the isolation layers described above (if present) or the lower gate electrodes 80L. The upper gate electrodes 80U may be disposed between the upper semiconductor nanostructures 26U. In some embodiments, the upper gate electrodes 80U wrap around the upper semiconductor nanostructures 26U. The upper gate electrodes 80U may be formed of the same or similar materials and formed by same or similar processes as the lower gate electrodes 80L. The upper gate electrodes 80U may be formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

Gate masks 92 may be formed on the upper gate structures 90U. The formation process may include recessing the upper gate structures 90U, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72 and to level top surfaces of the gate masks 92 and the second ILD 72. The planarization process may be a CMP process, an etch-back process, combinations thereof, or the like. After the planarization process, the top surfaces of the gate masks 92, the gate dielectrics 78, the second ILD 72, and the gate spacers 44 may be substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20'.

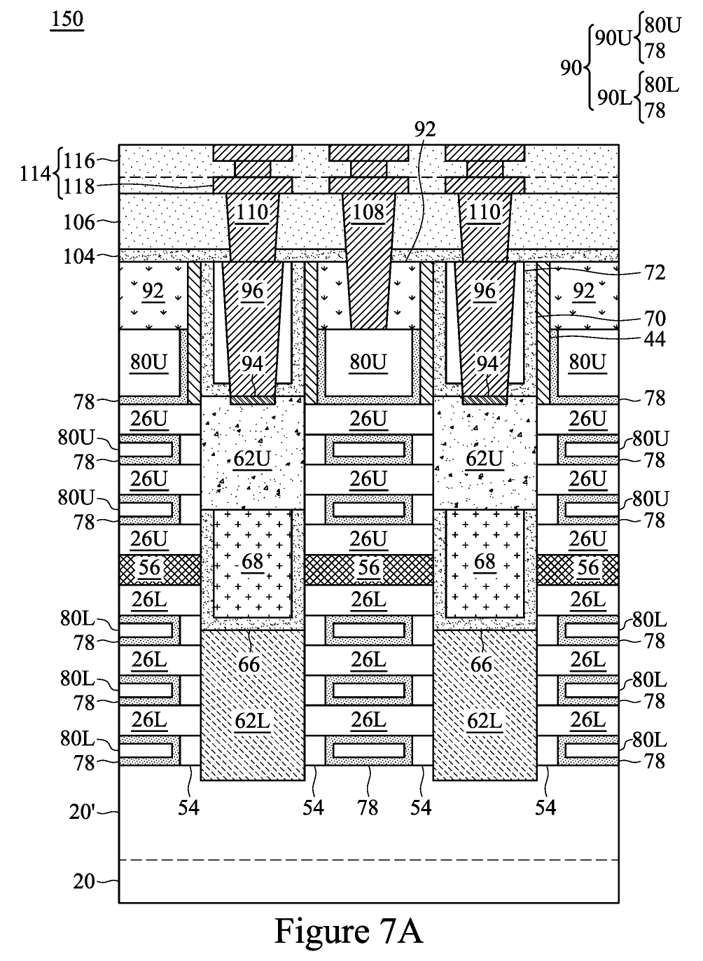

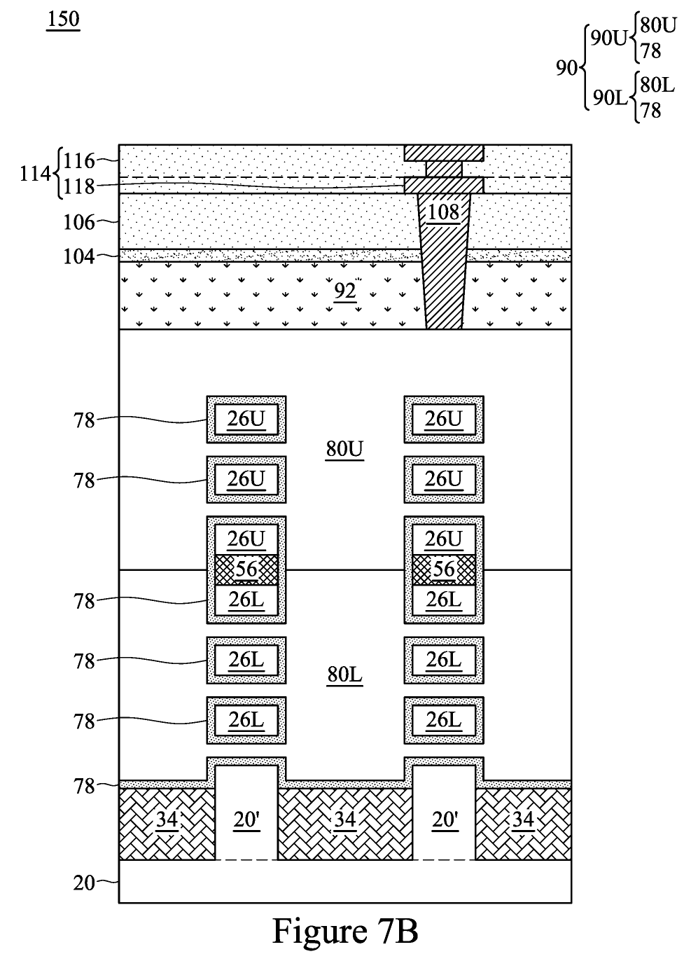

In FIGS. 7A and 7B, metal-semiconductor alloy regions 94 and source/drain contacts 96 are formed through the second ILD 72 to electrically couple to the upper epitaxial source/drain regions 62U and/or the lower epitaxial source/drain regions 62L. FIGS. 7A and 7B are cross-sectional views of a same structure, which may be referred to as an intermediate structure 150. FIG. 7A may be obtained along a reference cross-section that correspond to the reference cross-section A-A' shown in FIGS. 1 and 7B may be obtained along a reference cross-section that correspond to the reference cross-section B-B' as shown in FIG. 1.

As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

A third CESL 104 and a third ILD 106 are then formed. In some embodiments, the third CESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the third CESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the third ILD 106. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower epitaxial source/drain regions 62L may be made through a backside of the substrate 20 (e.g., a side opposite to the front-side interconnect structure 114).

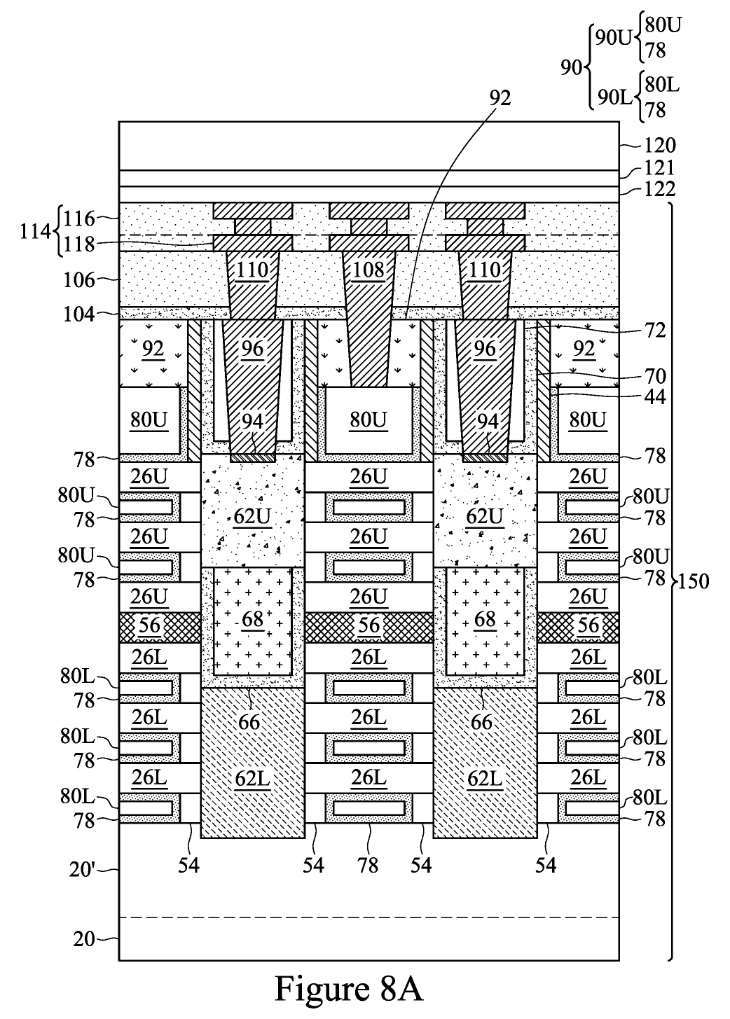

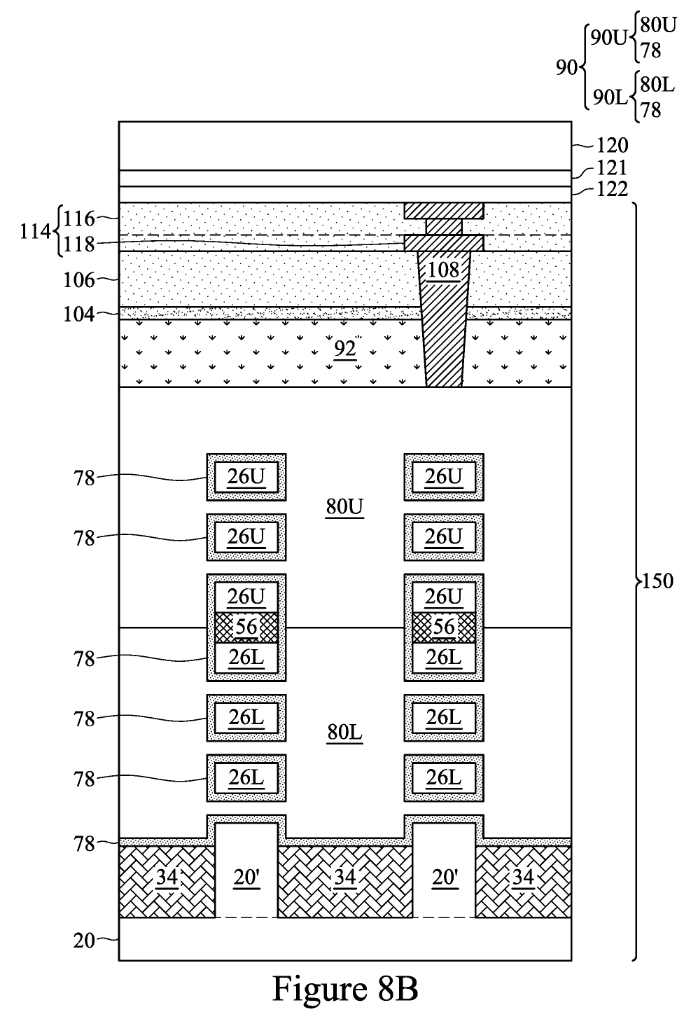

In FIGS. 8A and 8B, a carrier substrate 120 is bonded to the intermediate structure 150 by bonding layer 121 and bonding layer 122. The cross-sectional view in FIG. 8A may correspond to the cross-sectional view shown in FIG. 7A and the cross-sectional view in FIG. 8B may correspond to the cross-sectional view shown in FIG. 7B. The bonding layer 122 may be deposited on the front-side interconnect structure 114. The bonding layer 122 may comprise a material suitable for a subsequent dielectric-to-dielectric bonding process and may have a high thermal conductivity, such as a metal oxide. The bonding layer 122 may be formed of titanium oxide, aluminum oxide, nickel oxide, zinc oxide, or the like. The bonding layer 122 may be deposited by any suitable method, such as PVD, CVD, ALD, or the like. Then a planarization process, such as CMP or the like, may be used to remove excess material from a surface of the bonding layer 122 and to planarize the surface of the bonding layer 122 for subsequent processing.

The carrier substrate 120 may be a glass carrier substrate, a ceramic carrier substrate, a wafer (e.g., a silicon wafer), or the like. The bonding layer 121 may be deposited on the carrier substrate 120. The bonding layer 121 may comprise a material suitable for a dielectric-to-dielectric bonding process and may have a high thermal conductivity, such as a metal oxide. The bonding layer 121 may be formed of titanium oxide, aluminum oxide, nickel oxide, zinc oxide, or the like. In some embodiments, the bonding layer 122 and the bonding layer 121 may comprise a same material. The bonding layer 121 may be deposited and planarized by similar methods as described with respect to the bonding layer 122.

Then the carrier substrate 120 may be bonded to the intermediate structure 150 by bonding the bonding layer 121 and the bonding layer 122 through a dielectric-to-dielectric bonding process. The dielectric-to-dielectric bonding process may include first performing a surface treatment and a cleaning to the bonding layer 122 and the bonding layer 121. The surface treatment may be a plasma treatment or the like and the cleaning may be rinsing with deionized water or the like. Then the carrier substrate 120 is aligned with the intermediate structure 150, and the bonding layer 121 and the bonding layer 122 are pressed against each other to initiate bonding at room temperature. Afterwards, the bonding layer 121 and the bonding layer 122 may be annealed at a high temperature in a range from about 150° C to about 500° C. The annealing may lead to the formation of covalent bonds between the bonding layer 122 and the bonding layer 121.

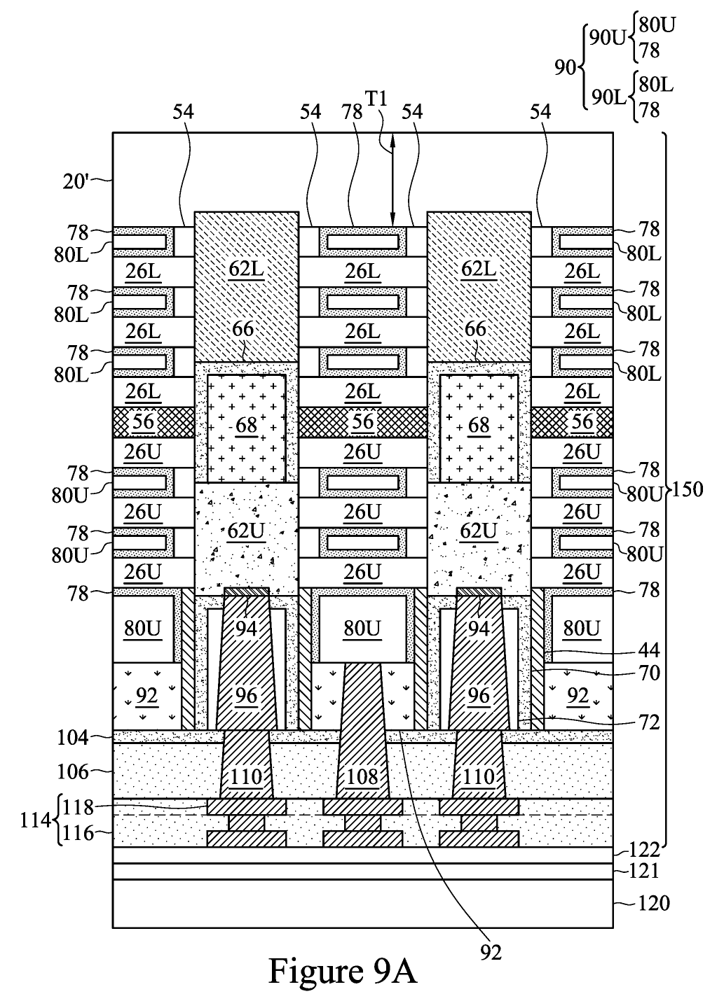

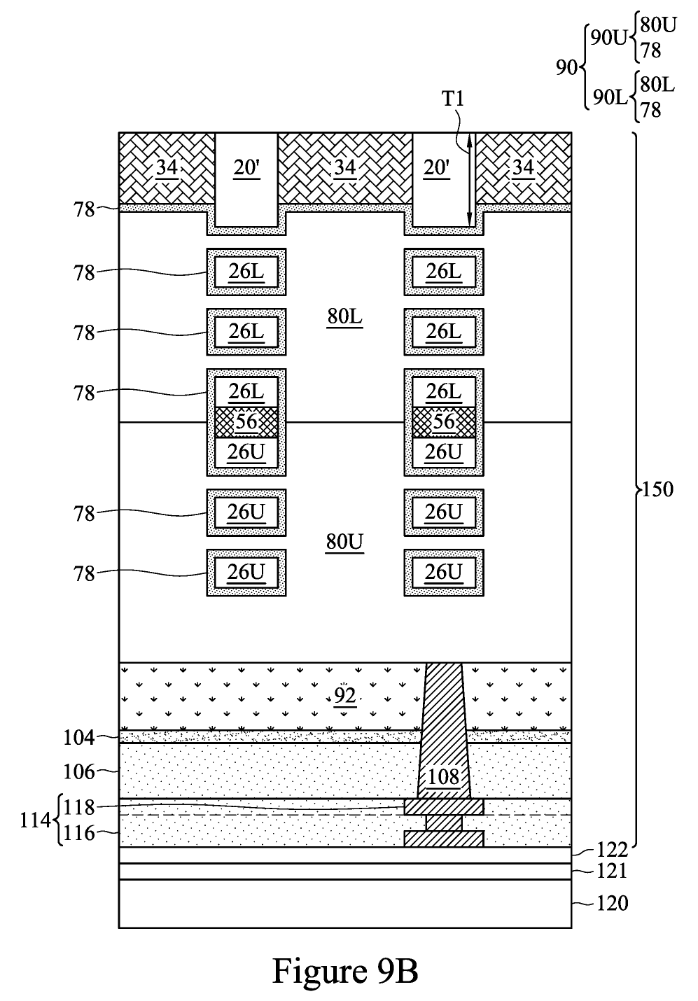

In FIGS. 9A and 9B, the intermediate structure 150 is flipped and a portion of the substrate 20 is removed. The cross-sectional view in FIG. 9A may correspond to the cross-sectional view shown in FIG. 8A and the cross-sectional view in FIG. 9B may correspond to the cross-sectional view shown in FIG. 8B. After the intermediate structure 150 is flipped, the substrate 20 may face upwards. Then a portion of the substrate 20 may be removed by a planarization process such as CMP or the like. After the planarization process, the STI regions 34 may be exposed and the semiconductor fins 20’ may remain between the STI regions 34. Top surfaces of the STI regions 34 and the semiconductor fins 20’ may be substantially coplanar (within process variations). The semiconductor fins 20’ may have a thickness T1 smaller than 100 nm. Such selected thickness may lead to sufficient doping of the semiconductor fins 20’ is a subsequent process.

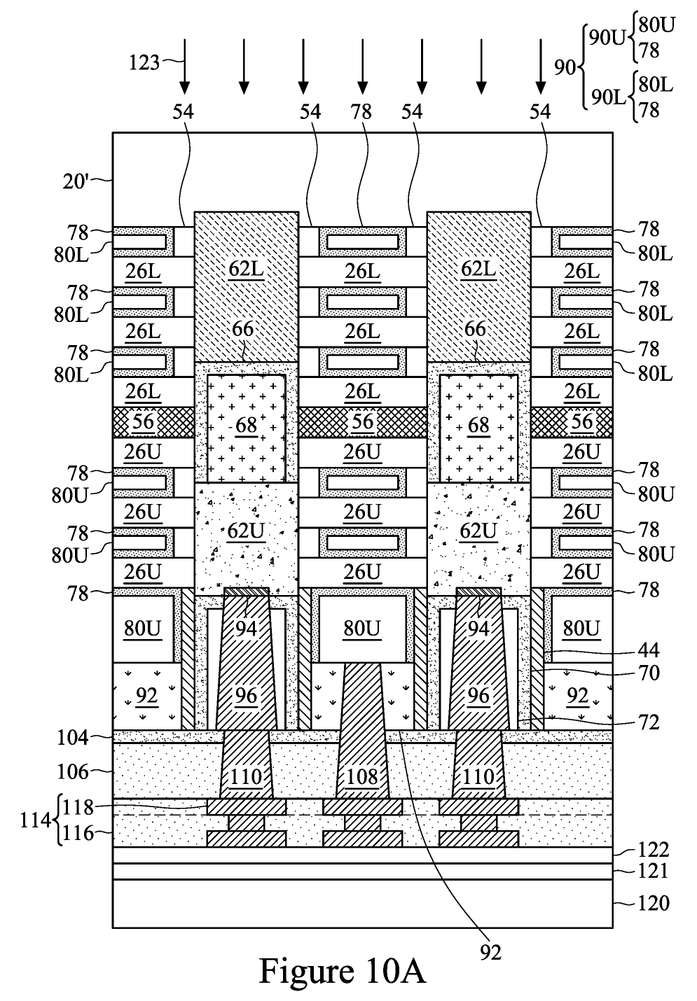

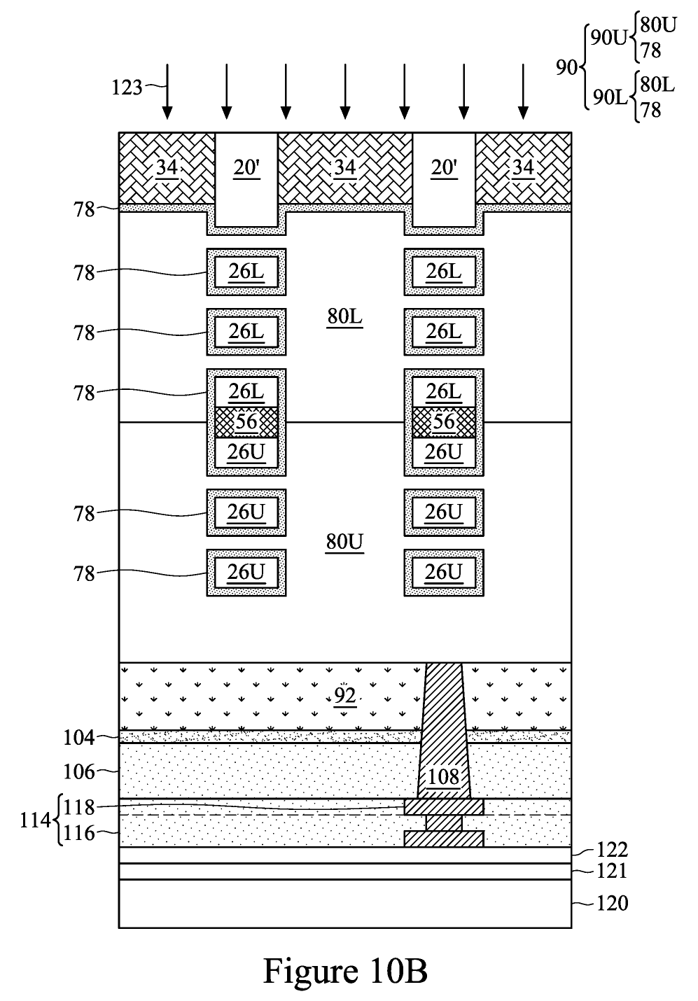

In FIGS. 10A and 10B, the semiconductor fins 20’ are doped (e.g., implanted, embedded) with a first dopant 123 by a doping process. The cross-sectional view in FIG. 10A may correspond to the cross-sectional view shown in FIG. 9A and the cross-sectional view in FIG. 10B may correspond to the cross-sectional view shown in FIG. 9B. The doping process may result in turning the semiconductor fins 20’ from being crystalline to being amorphous (e.g., amorphizing of the semiconductor fins 20’), which may lead to an effective removal of the semiconductor fins 20’ without damaging features adjacent the semiconductor fins 20’ during a subsequent etching process. In some embodiments, the STI regions 34 may remain exposed during the doping process, and as a result, may also be doped with the first dopant 123 during the doping process.

The first dopant may comprise one or more elements different from the element(s) in the material of the semiconductor fins 20’ and/or the element(s) in the material of the STI regions 34 before the doping process. The first dopant may be chlorine, oxygen, phosphorous, nitrogen, silicon, germanium, hydrogen, helium, argon, or the like. Once the first dopant 123 is doped (e.g., implanted, embedded) in the semiconductor fins 20’, atoms of the first dopant 123 may disrupt the ordering and/or bonding of atoms in the semiconductor fins 20’, which may result in the amorphization of the semiconductor fins 20’. As a result, the semiconductor fins 20’ may be amorphous after the doping process, which may promote an etching rate and etch selectivity during the subsequent etching process. In the embodiments shown in FIGS. 10A and 10B, the semiconductor fins 20’ are completely doped with the first dopant as an example. In other embodiments as described in greater detail later, the semiconductor fins 20’ are partially doped with the first dopant.

The doping concentration of the first dopant in the semiconductor fins 20’ and the STI regions 34 may be smaller than about 1 x 10²⁰ cm⁻³. Such selected doping concentration of the first dopant in the semiconductor fins 20’ may cause sufficient amorphization of the semiconductor fins 20’, which may lead to the effective removal of the semiconductor fins 20’ in the subsequent etching process. The doping process may be performed by a suitable doping process in a suitable tool. In some embodiments, the doping process is performed in a dry etching tool with a radio frequency power set at a value smaller than about 1000 W to achieve the said selected doping concentration of the first dopant. In some embodiments, the doping process is performed in a PVD tool with a radio frequency power set at a value smaller than about 1000 W to achieve the said selected doping concentration of the first dopant. In some embodiments, the doping process is performed in an implantation tool with a source acceleration voltage set at a value smaller than about 50 keV to achieve the said selected doping concentration of the first dopant. Other doping tools may be used on other embodiments.

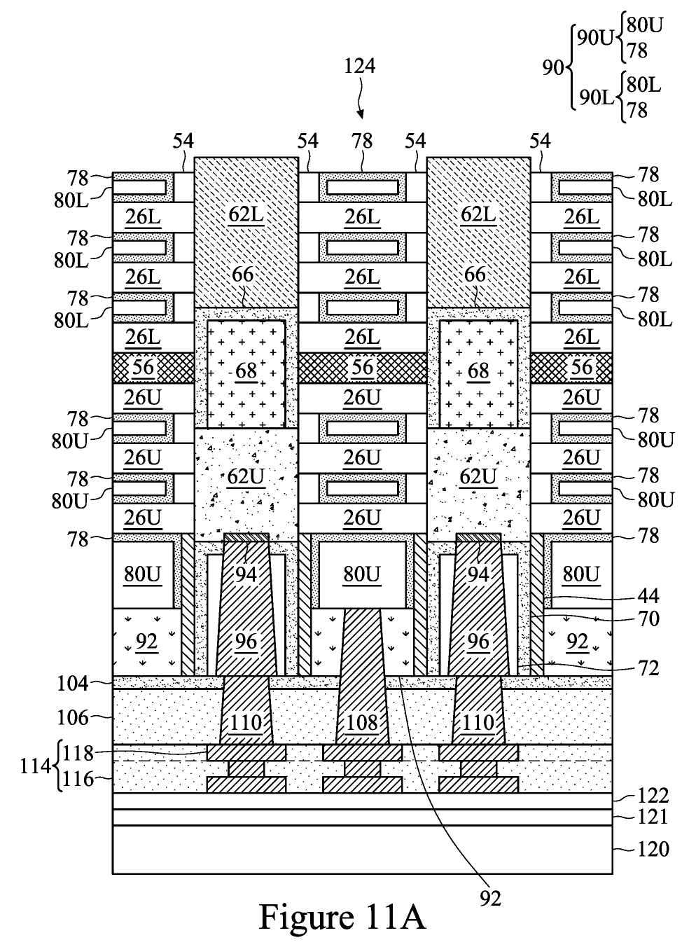

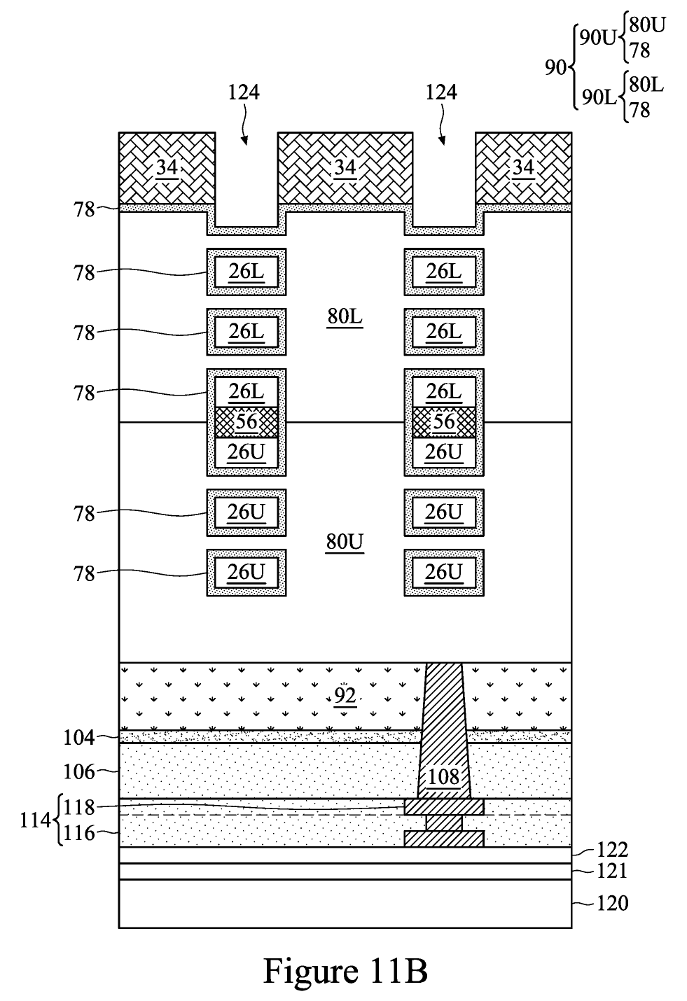

In FIGS. 11A and 11B, openings 124 are formed by removing the semiconductor fins 20’. The cross-sectional view in FIG. 11A may correspond to the cross-sectional view shown in FIG. 10A and the cross-sectional view in FIG. 11B may correspond to the cross-sectional view shown in FIG. 10B. The semiconductor fins 20’ may be removed by a suitable etching process, such as an isotropic wet etching process using an etching solution with a pH value greater than 7. The etching solution may be an aqueous solution comprising tetramethylammonium hydroxide, potassium hydroxide, ammonium hydroxide, or the like. After the removal of the semiconductor fins 20’, upper surfaces of the gate dielectrics 78, top surfaces and sidewalls of the lower epitaxial source/drain regions 62L, top surfaces of the inner spacers 54, as well as sidewalls of the STI regions 34 are exposed.

Due to the amorphization of the semiconductor fins 20’, an etching rate of the semiconductor fins 20’ is increased during the etching process using the said etching solution. For example, the amorphization of the semiconductor fins 20' may increase the etch selectivity of the semiconductor fins 20' with respect to the lower gate structures 90L, the lower epitaxial source/drain regions 62L, and/or the STI regions 34. Therefore, the semiconductor fins 20’ may be completely removed while the lower gate structures 90L (including the gate dielectrics 78 and the lower gate electrodes 80L), the lower epitaxial source/drain regions 62L, or the STI regions 34 may remain substantially intact during the etching process. As a result, the performance and reliability of the subsequently formed stacking transistor may be improved.

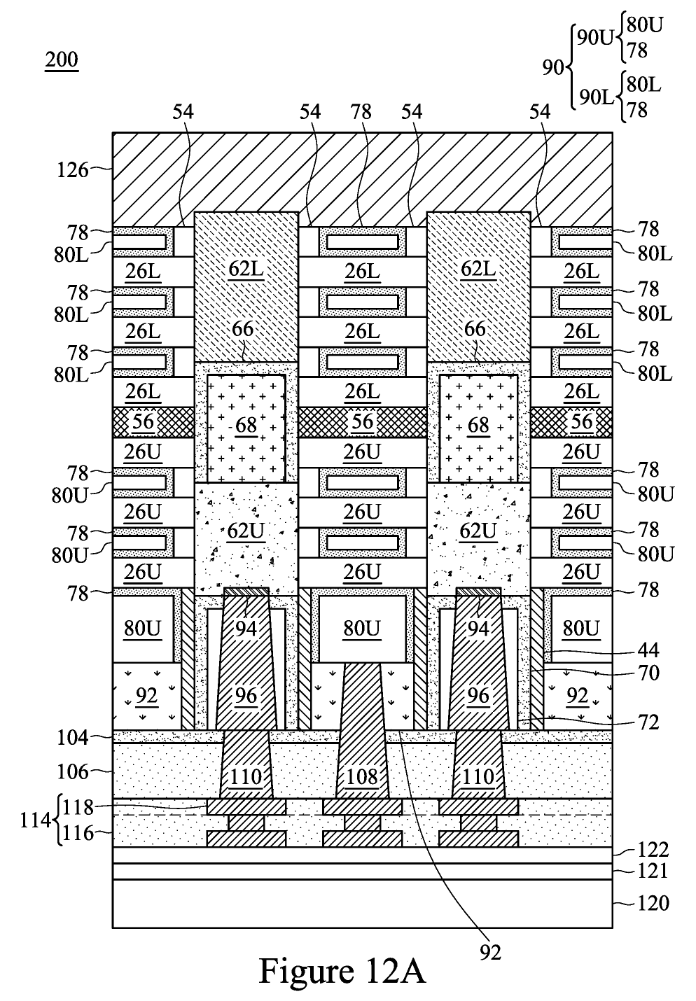

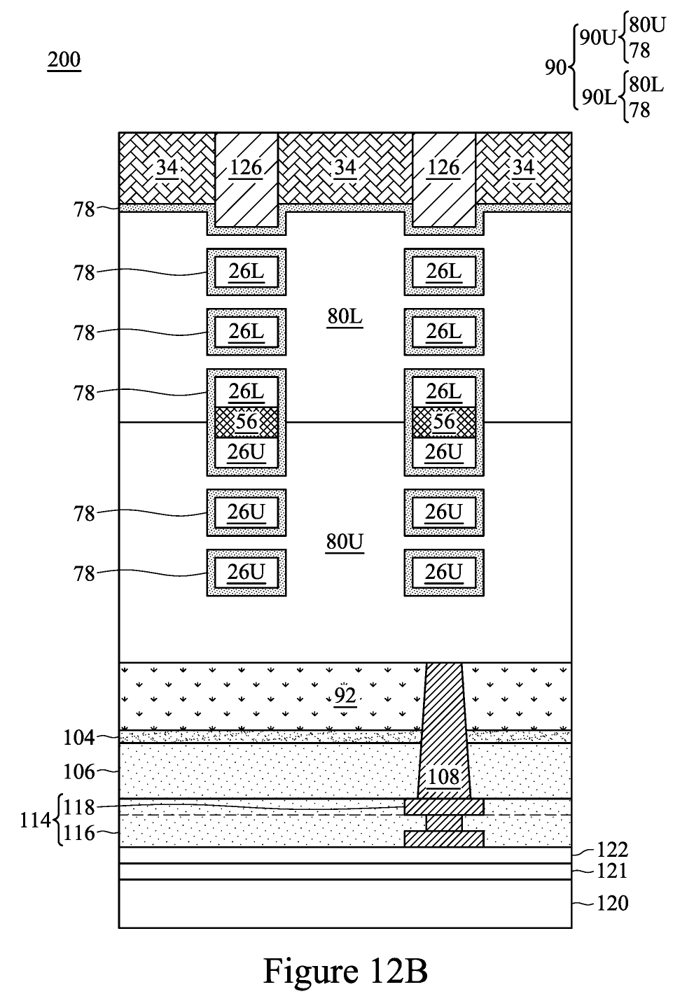

In FIGS. 12A and 12B, dielectric layers 126 are formed in the openings 124. The cross-sectional view in FIG. 12A may correspond to the cross-sectional view shown in FIG. 11A and the cross-sectional view in FIG. 12B may correspond to the cross-sectional view shown in FIG. 11B. The dielectric layers 126 may cover the upper surfaces of the gate dielectrics 78, the top surfaces and the sidewalls of the lower epitaxial source/drain regions 62L, the top surfaces of the inner spacers 54, as well as the sidewalls of the STI regions 34. The dielectric layers 126 may be between neighboring STI regions 34. The dielectric layers 126 may comprise silicon oxide or the like. In some embodiments, the dielectric layers 126 and the STI regions 34 comprise different materials. In some embodiments, the dielectric layers 126 and the STI regions 34 comprise a same material with the STI regions 34 further comprising the first dopant 123 due to exposure during the doping process described above. Further, the dielectric layer 126 may be substantially free of the first dopant 123 as the dielectric layer 126 is deposited after the doping process described above is performed.

The dielectric layers 126 may be formed by a suitable deposition process, such as CVD, ALD, or the like. Then a planarization process, such as CMP or the like, may be performed to remove excess deposited material. After the planarization process, top surfaces of the dielectric layers 126 and the STI regions 34 may be substantially coplanar (within process variations). Conductive contacts similar to the gate contacts 108 and the source/drain contacts 96 may be formed through the dielectric layers 126 to electrically connect to the lower epitaxial source/drain regions 62L and the lower gate structures 90L. The structure shown in FIGS. 12A and 12B may be referred to as the stacking transistor 200.

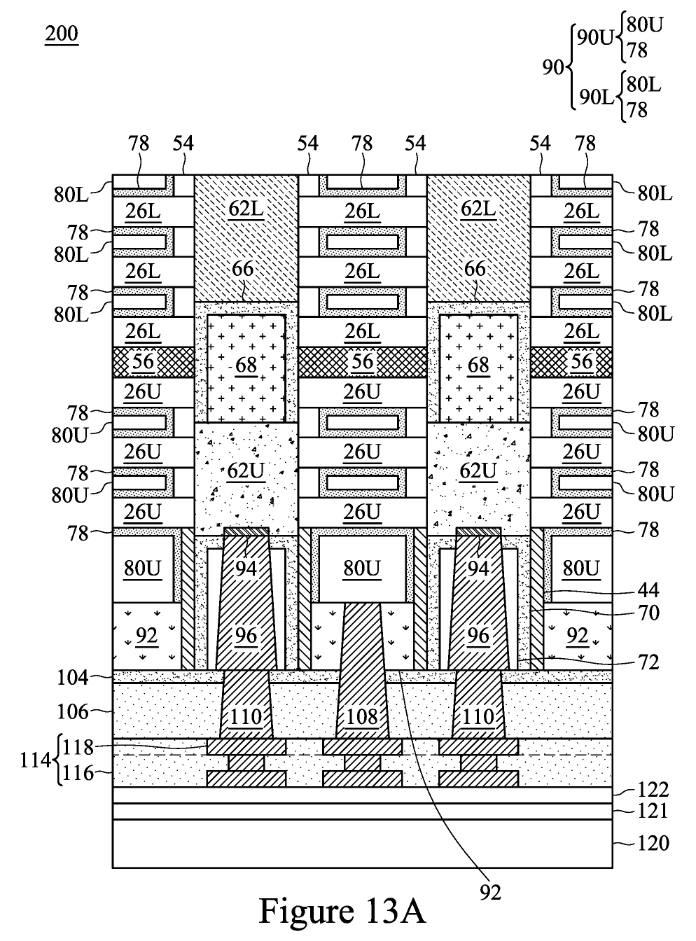

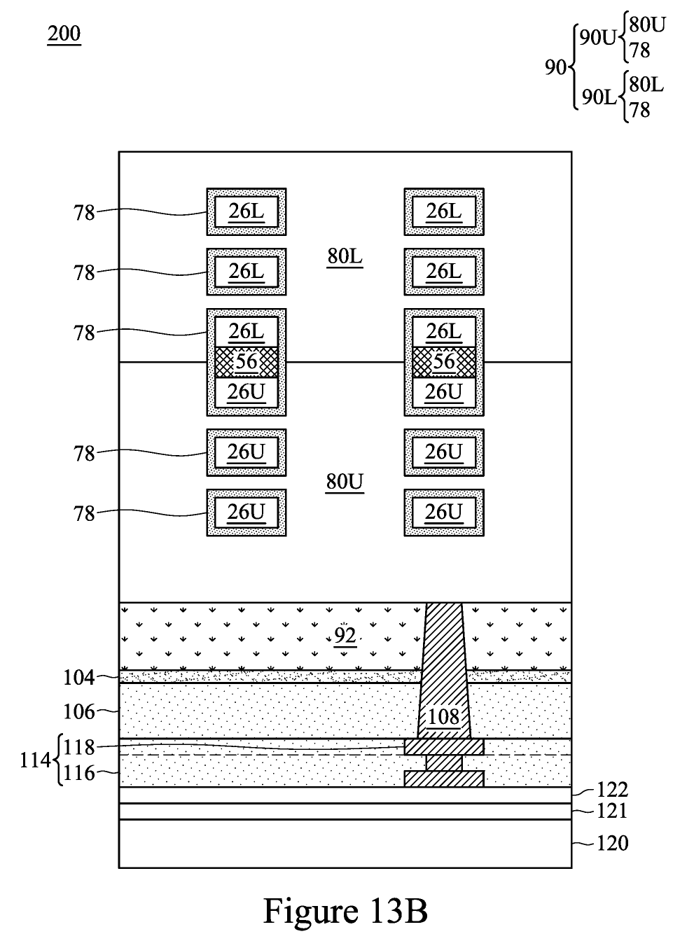

FIGS. 13A and 13B show a stacking transistor 200 in accordance to some alternative embodiments similar to the embodiments shown in FIGS. 12A and 12B, where like reference numerals indicate like elements formed by like processes. The cross-sectional view in FIG. 13A may correspond to the cross-sectional view shown in FIG. 12A and the cross-sectional view in FIG. 13B may correspond to the cross-sectional view shown in FIG. 12B. In the embodiments shown in FIGS. 13A and 13B, the dielectric layers 126, the STI regions 34, and portions of the lower epitaxial source/drain regions 62L, the inner spacers 54, and the gate dielectrics 78 are removed by the planarization process. As a result, the lower gate electrodes 80L, the gate dielectrics 78, the inner spacers 54, and the lower epitaxial source/drain regions 62L may be exposed. Top surfaces of the lower gate electrodes 80L, the gate dielectrics 78, the inner spacers 54, and the lower epitaxial source/drain regions 62L may be substantially coplanar (within process variations).

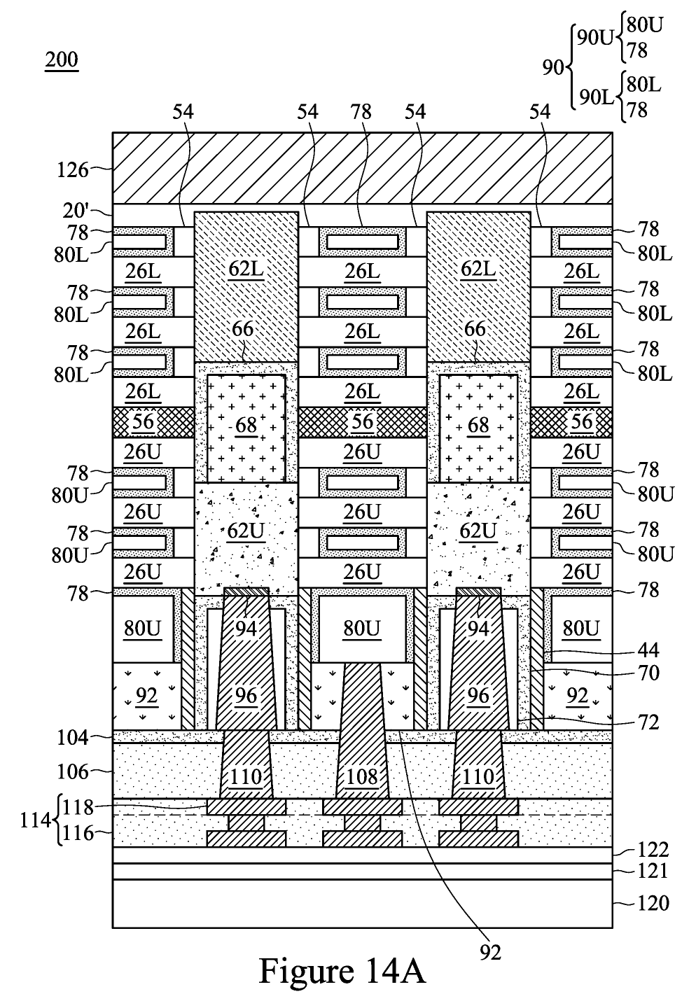

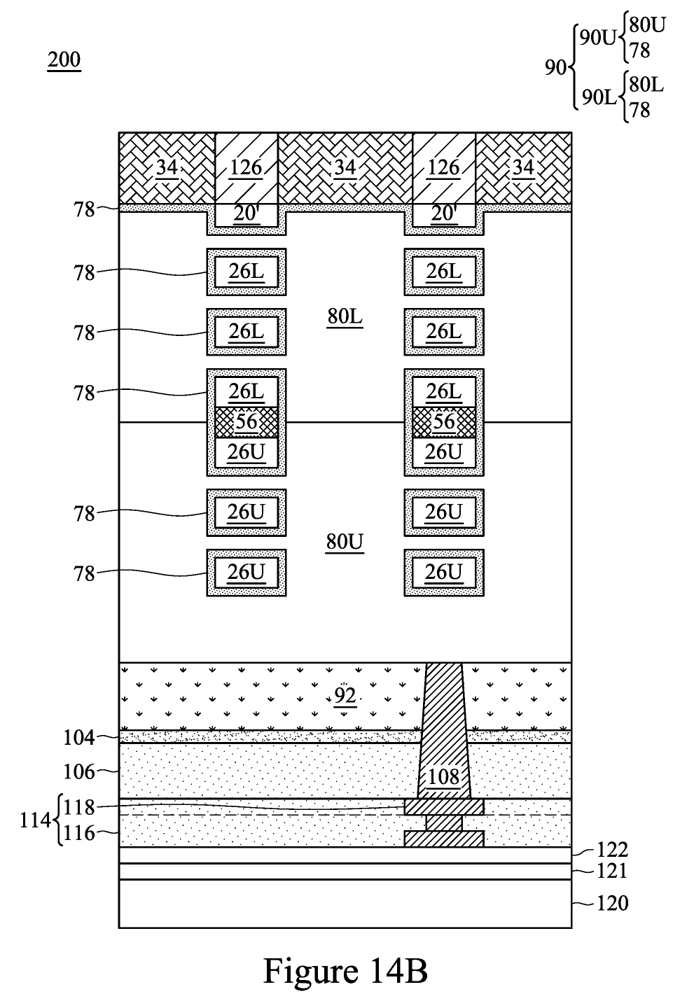

FIGS. 14A and 14B show a stacking transistor 200 in accordance to some alternative embodiments similar to the embodiments shown in FIGS. 12A and 12B, where like reference numerals indicate like elements formed by like processes. The cross-sectional view in FIG. 14A may correspond to the cross-sectional view shown in FIG. 12A and the cross-sectional view in FIG. 14B may correspond to the cross-sectional view shown in FIG. 12B. In the embodiments shown in FIGS. 14A and 14B, portions of the semiconductor fins 20' remain in the stacking transistor 200, which may be due to the partial amorphization of the semiconductor fins 20’ during the doping process of the semiconductor fins 20’. The portions of the semiconductor fins 20' remain in the stacking transistor 200 may be undoped and may remain crystalline after the doping process, thereby remaining substantially intact during the subsequent etching process. For example, the doping process may result in etch selectivity between the amorphous (e.g., doped) portions of the semiconductor fins 20' and the crystalline (e.g., undoped) portions of the semiconductor fins 20'. The semiconductor fins 20' may cover the upper surfaces of the gate dielectrics 78, the top surfaces and the sidewalls of the lower epitaxial source/drain regions 62L, and the top surfaces of the inner spacers 54. The semiconductor fins 20' may separate the dielectric layers 126 from the gate dielectrics 78, the lower epitaxial source/drain regions 62L, and the inner spacers 54. In some embodiments, the semiconductor fins 20' are separated from the STI regions 34 by the dielectric layers 126.

The embodiments of the present disclosure have some advantageous features. Due to the amorphization of the semiconductor fins 20’ by doping the semiconductor fins 20’ with the first dopant 123, the semiconductor fins 20’ may be completely removed while the lower gate structures 90L (including the gate dielectrics 78 and the lower gate electrodes 80L), the lower epitaxial source/drain regions 62L, or the STI regions 34 may remain substantially intact during the etching process. As a result, the performance and reliability of the stacking transistor 200 may be improved.

In an embodiment, a semiconductor device includes a first source/drain region; a first nanostructure on a sidewall of the first source/drain region; a first gate structure around the first nanostructure; a first isolation region and a second isolation region on the first gate structure, wherein the first isolation region and the second isolation region each include a first dielectric material and a first dopant; and a dielectric layer over the first source/drain region and the first gate structure, wherein the dielectric layer extends between the first isolation region and the second isolation region, wherein the dielectric layer includes a second dielectric material, and wherein the dielectric layer is free of the first dopant. In an embodiment, the second dielectric material is different from the first dielectric material. In an embodiment, the first dielectric material is silicon oxide or silicon nitride. In an embodiment, the first dopant is chlorine, oxygen, phosphorous, nitrogen, germanium, hydrogen, helium, or argon. In an embodiment, the dielectric layer is in contact with the first source/drain region and the first gate structure. In an embodiment, the semiconductor device further includes a semiconductor layer, wherein the semiconductor layer is between the dielectric layer and the first source/drain region, and wherein the semiconductor layer is between the dielectric layer and the first gate structure. In an embodiment, the semiconductor layer is separated from the first isolation region and the second isolation region by the dielectric layer.

In an embodiment, a method of forming a semiconductor device includes depositing an isolation region on a sidewall of a semiconductor fin, wherein the semiconductor fin is crystalline; forming a first nanostructure over the semiconductor fin and the isolation region; growing a first source/drain region, wherein the first nanostructure is on a sidewall of the first source/drain region; forming a first gate structure wrapping around the first nanostructure; embedding a first dopant in at least a first portion of the semiconductor fin, wherein the first portion of the semiconductor fin is amorphous after embedding the first dopant in the first portion of the semiconductor fin; forming a first opening by removing the first portion of the semiconductor fin; and depositing a dielectric layer in the first opening. In an embodiment, the isolation region is on a sidewall of the dielectric layer, and wherein the isolation region and the dielectric layer include different materials. In an embodiment, the method further includes embedding the first dopant in the isolation region. In an embodiment, the first dopant includes a first element different from elements of a material of the isolation region. In an embodiment, a second portion of the semiconductor fin is crystalline and free of the first dopant after embedding the first dopant in the first portion of the semiconductor fin, wherein the second portion of the semiconductor fin is between the dielectric layer and the first source/drain region, and wherein the second portion of the semiconductor fin is between the dielectric layer and the first gate structure. In an embodiment, embedding the first dopant in at least the first portion of the semiconductor fin embeds the first dopant in an entirety of the semiconductor fin, and wherein the entirety of the semiconductor fin is amorphous after embedding the first dopant in the entirety of the semiconductor fin, and wherein forming the first opening removes the entirety of the semiconductor fin. In an embodiment, the dielectric layer is in contact with the first source/drain region and the first gate structure.

In an embodiment, a method of forming a semiconductor device includes depositing an isolation region on a sidewall of a semiconductor fin; forming a first nanostructure and a second nanostructure over the semiconductor fin and the isolation region; growing a first source/drain region, wherein the first nanostructure is on a sidewall of the first source/drain region; growing a second source/drain region over the first source/drain region, wherein the second nanostructure is on a sidewall of the second source/drain region; forming a first gate structure around the first nanostructure and a second gate structure around the second nanostructure; implanting a first dopant in at least a first portion of the semiconductor fin and at least a first portion of the isolation region; forming a first opening by removing the first portion of the semiconductor fin, wherein the first opening exposes a sidewall of the isolation region; and depositing a dielectric layer in the first opening and on the sidewall of the isolation region. In an embodiment, implanting the first dopant in the first portion of the semiconductor fin amorphizes the first portion of the semiconductor fin. In an embodiment, removing the first portion of the semiconductor fin includes performing a wet etching process using an etching solution, and wherein a pH value of the etching solution is greater than 7. In an embodiment, implanting the first dopant in at least the first portion of the semiconductor fin implants the first dopant in an entirety of the semiconductor fin, and wherein the first source/drain region and the first gate structure are exposed after forming the first opening. In an embodiment, the first dopant is chlorine, oxygen, phosphorous, nitrogen, silicon, germanium, hydrogen, helium, or argon. In an embodiment, the method further includes removing the dielectric layer by a polishing process, wherein the first source/drain region and the first gate structure are exposed after removing the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first source/drain region;
a first nanostructure on a sidewall of the first source/drain region;
a first gate structure around the first nanostructure;
a second source/drain region;
a second nanostructure on a sidewall of the second source/drain region;
a second gate structure around the second nanostructure;
a dielectric isolation layer between the first nanostructure and the second nanostructure;
an isolation region on the first gate structure, the isolation region comprising a first dielectric material and a first dopant; and
a dielectric layer on the first source/drain region and the first gate structure, the dielectric layer comprising a second dielectric material, the dielectric layer free of the first dopant, wherein the first gate structure is between the second gate structure and the dielectric layer.

2. The semiconductor device of claim 1, wherein the second dielectric material is different from the first dielectric material.

3. The semiconductor device of claim 1, wherein the first dielectric material is silicon oxide or silicon nitride.

4. The semiconductor device of claim 1, wherein the first dopant is chlorine, oxygen, phosphorous, nitrogen, silicon, germanium, hydrogen, helium, or argon.

5. The semiconductor device of claim 1, wherein the dielectric layer is in contact with the first source/drain region and the first gate structure.

6. The semiconductor device of claim 1, wherein the dielectric isolation layer comprises a carbon-containing dielectric material.

7. The semiconductor device of claim 1, wherein the first source/drain region and the second source/drain region have opposite conductivity types.

8. A semiconductor device comprising:
a first source/drain region;
a first nanostructure on a sidewall of the first source/drain region;
a gate dielectric on the first nanostructure;
a gate electrode on the gate dielectric;
an inner spacer between the first source/drain region and the gate electrode;
a semiconductor fin on the gate dielectric, on a top surface and a sidewall of the first source/drain region, and on the inner spacer, wherein the semiconductor fin is crystalline;
a dielectric layer on the semiconductor fin, wherein the semiconductor fin is between the dielectric layer and the gate dielectric, between the dielectric layer and the first source/drain region, and between the dielectric layer and the inner spacer; and
an isolation region on a sidewall of the dielectric layer, wherein the semiconductor fin is separated from the isolation region by the dielectric layer.

9. The semiconductor device of claim 8, wherein the semiconductor fin comprises silicon.

10. The semiconductor device of claim 8, wherein the isolation region comprises a dielectric material and a first dopant, and wherein the dielectric layer is free of the first dopant.

11. The semiconductor device of claim 8, further comprising:
a second nanostructure;
a second source/drain region on a sidewall of the second nanostructure;
a second gate electrode around the second nanostructure; and
a dielectric isolation layer between the first nanostructure and the second nanostructure.

12. The semiconductor device of claim 8, wherein the gate electrode wraps around the first nanostructure.

13. The semiconductor device of claim 8, wherein the dielectric layer comprises silicon oxide.

14. A method of forming a semiconductor device, the method comprising:
forming a nanostructure over a semiconductor fin, wherein the semiconductor fin is a patterned portion of a substrate;
growing a source/drain region on a sidewall of the nanostructure;
forming a gate structure around the nanostructure;
forming an interconnect structure over the gate structure and the source/drain region;
bonding a carrier substrate to the interconnect structure;
flipping the substrate and the carrier substrate;
removing a portion of the substrate to expose the semiconductor fin, wherein the semiconductor fin has a thickness smaller than 100 nm after removing the portion of the substrate;
doping the semiconductor fin with a first dopant, wherein the semiconductor fin is amorphous after doping the semiconductor fin with the first dopant;
removing the semiconductor fin to form an opening; and
depositing a dielectric layer in the opening.

15. The method of claim 14, further comprising depositing an isolation region on a sidewall of the semiconductor fin, wherein doping the semiconductor fin with the first dopant further dopes the isolation region with the first dopant.

16. The method of claim 14, wherein removing the semiconductor fin comprises performing a wet etching process using an etching solution having a pH value greater than 7.

17. The method of claim 16, wherein the etching solution comprises tetramethylammonium hydroxide, potassium hydroxide, or ammonium hydroxide.

18. The method of claim 14, wherein a doping concentration of the first dopant in the semiconductor fin is smaller than 1 x 10²⁰ cm⁻³.

19. The method of claim 14, wherein the first dopant is chlorine, oxygen, phosphorous, nitrogen, silicon, germanium, hydrogen, helium, or argon.

20. The method of claim 14, further comprising, after depositing the dielectric layer, performing a planarization process, wherein the source/drain region and the gate structure are exposed after the planarization process.
